(19) United States
(12) Patent Application Publication
(10) Pub. No.: US 2021/0178523 A1
(43) Pub. Date: Jun. 17, 2021

(54) PART FOR SUBSTRATE PROCESSING APPARATUS AND SUBSTRATE PROCESSING SYSTEM

(71) Applicant: TOKYO ELECTRON LIMITED, Tokyo (JP)

(72) Inventors: Michishige Saito, Miyagi (JP); Sho Yamahira, Miyagi (JP)

(73) Assignee: TOKYO ELECTRON LIMITED, Tokyo (JP)

(21) Appl. No.: 17/118,158

(22) Filed: Dec. 10, 2020

(30) Foreign Application Priority Data
Dec. 12, 2019 (JP) 2019-224852

(51) Int. Cl. B23K 26/364; B23K 26/00; G06K 7/14

(52) U.S. Cl. CPC B23K 26/364; G06K 7/1417; B23K 26/0093

(57) ABSTRACT

A part for substrate processing apparatus includes a marker with at least one of a surface and an inside of the part processed. The marker is configured such that two-dimensional code information is readable by at least one of a groove formed in the part by processing and two or more types of colors.

### CROSS-REFERENCE TO RELATED APPLICATION

This application is based on and claims priority from Japanese Patent Application No. 2019-224852 filed on Dec. 12, 2019 with the Japan Patent Office, the disclosure of which is incorporated herein in its entirety by reference.

### TECHNICAL FIELD

The present disclosure relates to a part for substrate processing apparatus and a substrate processing system.

### BACKGROUND

A part management may be performed by attaching a tape displaying the serial number of the part to the part. For example, the part management at the manufacturing site of a substrate processing apparatus is performed by manually inputting and recording the serial number of the part displayed on the tape attached to the part, and confirming which part is mounted on the substrate processing apparatus. See, for example, Japanese Patent Laid-Open Publication No. H04-146649.

### SUMMARY

According to an aspect of the present disclosure, a part for substrate processing apparatus include a marker with a surface and/or an inside of the part processed. The marker is configured such that two-dimensional code information is readable by a groove formed in the part by processing and/or two or more types of colors.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a view illustrating an example of a marker engraved on a part according to an embodiment

FIG. 2 is a view illustrating a material of a part and a state of engraved on the part according to the embodiment.

FIG. 3 is a view illustrating a substrate processing system according to the embodiment.

FIG. 4 is a schematic cross-sectional view illustrating a substrate processing apparatus according to the embodiment.

FIG. 5 is a view illustrating an example of a part management system according to the embodiment.

FIG. 6 is a view illustrating an example of information on a part included in two-dimensional code information according to the embodiment.

FIG. 7 is a view illustrating an example of usable information set for each user according to the embodiment.

### DETAILED DESCRIPTION

In the following detailed description, reference is made to the accompanying drawings, which form a part thereof. The illustrative embodiments described in the detailed description, drawings, and claims are not meant to be limiting. Other embodiments may be utilized, and other changes may be made without departing from the spirit or scope of the subject matter presented here.

Hereinafter, embodiments for carrying out the present disclosure will be described with reference to the accompanying drawings. In each of the drawings, the same elements may be designated by the same reference numerals and redundant descriptions may be omitted.

[Engraving of Part]

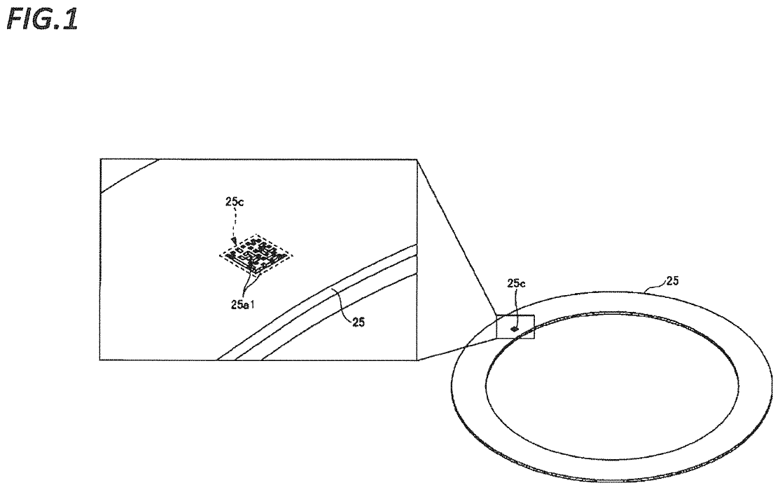

First, engraving a marker on a part according to an embodiment will be described with reference to FIG. 1. FIG. 1 is a view illustrating an example of a marker engraved on the part according to the embodiment. The part of FIG. 1 is an edge ring 25 arranged in a substrate processing apparatus, and is an example of a part for the substrate processing apparatus.

A marker 25c is formed on the surface of the edge ring 25. The marker 25c is an engraving processed on the surface of the part, and has a two-dimensional code in which informationon the edge ring 25 is formed into a graphic by grooves 25a1 formed in the edge ring 25. The code formed on the marker 25c may be a two-dimensional code such as a quick response (QR) code, a data matrix, or a barcode, or may be a three-dimensional code. In the embodiment, the two-dimensional code information may be acquired from the marker 25c.

The marker 25c is embedded in the edge ring 25 by directly processing the edge ring 25 with, for example, a laser, and is not a sticker attached to the edge ring 25 and is not drawn directly on the edge ring 25. Therefore, even when the surface of the edge ring 25 is worn out due to repeated processes (etching of a substrate) in the substrate processing apparatus, it is possible to prevent the marker 25c from being lost by digging a groove having a predetermined depth. As a result, the two-dimensional code information embedded in the marker 25c may be read by the reader, and the two-dimensional code information may be managed integrally with the edge ring 25. The two-dimensional code information may be read by a portable reader or a reader mounted on the apparatus.

Further, in the case of a sticker-type marker attached to the edge ring 25 or a marker drawn directly on the edge ring 25, when the edge ring 25 is worn out, the marker 25c may be peeled off or disappear. This may contaminate the substrate processing apparatus and adversely affect the process.

However, in the embodiment, the edge ring 25 is directly processed to dig a groove 25a1 in the edge ring 25 itself to form a marker 25c. The part used in the substrate processing apparatus is composed of members that do not adversely affect the process performed in the substrate processing apparatus. Therefore, even when the marker 25c is worn out together with the edge ring 25, the process is not adversely affected. From the above, by engraving the marker 25c on the part for the substrate processing apparatus according to the embodiment, it is possible to avoid adverse effects on the process, improve the efficiency of the part management, and improve the management accuracy.

The two-dimensional code information contained in the marker 25c may be read by the contrast of light generated by the light which is emitted from the reader to the marker 25c and reflected by the groove 25a1 of the marker 25c. The position of the marker 25c is the upper surface of the edge ring 25 in the example of FIG. 1, but is not limited thereto. For example, when the edge ring 25 is arranged in the substrate processing apparatus, the marker 25c is preferably positioned on a surface that is not exposed to plasma (e.g., a side surface). As a result, the wear of the marker 25c may be suppressed. However, the position of the marker 25c is not limited thereto.

[Engraving]

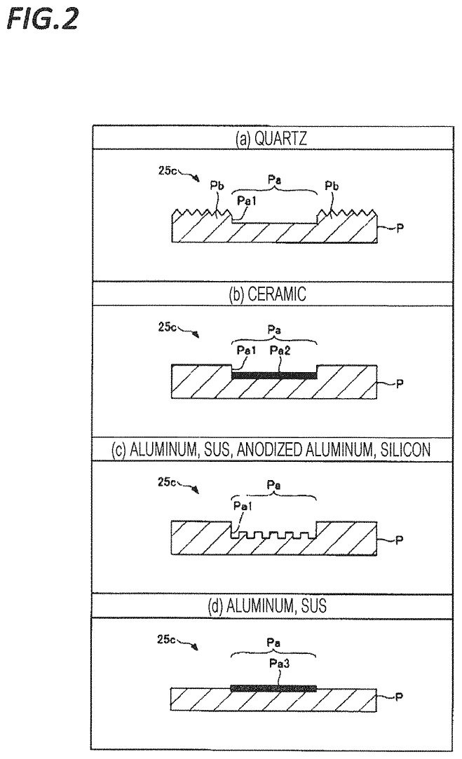

Next, the material of the part and the engraving method will be described with reference to FIG. 2. FIG. 2 is a view illustrating a material of the part P and a state of being engraved thereon according to the embodiment. In FIG. 2, a part of the region Pa of the region indicated by the marker 25c in FIG. 1 is illustrated in a simplified manner.

The marker 25c is engraved on the part P by heat-processing the part P with a laser. Portion (a) of FIG. 2 illustrates a state of a part of the region Pa of the marker 25c engraved on the part P when the part P is quartz. The marker 25c includes a groove Pa1 formed in the part P by laser processing.

When the part P is quartz, the marker 25c is engraved on the part P by irradiating the quartz with a laser to heat and melt an engraved portion including the region Pa to form an unevenness. Thus, the amount of reflected light changes between the portion of the groove Pa1 that has been incited and smoothed and the portion Ph of the sand-polished glass, resulting in a contrast of light.

As a result, when the light output from the reader hits the marker 25c, the reader reads two-dimensional code information from the contrast between the light incident on the groove Pa1 formed on the surface of the part P and the light incident on the portion Pb of the surface from the marker 25c formed on the part P. Thus, information on the part P such as the part number, serial number, and date of manufacture of the part P included in the two-dimensional code information may be acquired.

Portion (b) of FIG. 2 illustrates a state of a part of the region Pa of the marker 25c engraved on the part P when the part P is ceramic. The marker 25c includes a groove Pa1 formed in the part P by laser processing, a color of a portion Pa2 discolored by laser processing, and a color of the part P before discoloration.

When the part P is ceramic, the marker 25c is engraved on the part P by irradiating the ceramic with a laser to heat and melt the region Pa to form an unevenness. Thus, the amount of reflected light changes between the portion of the groove Pa1 that has been melted and smoothed and the other portions, resulting a contrast of light, In addition, the heated region Pa is discolored. Since the region other than the heated region Pa has the color of the ceramic before discoloration, a contrast of color occurs between the color of the discolored portion Pa2 and the other portions.

As a result, when the light output from the reader hits the marker 25c, the reader reads the contrast between the light incident on the groove Pa1 formed on the surface of the part P and the light incident on the other portions of the surface from the marker 25c formed on the part P. At the same time, the reader reads the contrast between the color of the discolored portion Pa2 and the color of the other portions from the marker 25c formed on the part P. Then, the reader reads the two-dimensional code information from the read contrast of light and the read contrast of color. Thus, information on the part P such as the part number, serial number, and date of manufacture of the part P included in the two-dimensional code information may be acquired.

Portion (c) of FIG. 2 illustrates a state of a part of the region Pa of the marker 25c engraved on the part P when the part P is aluminum, stainless steel (SUS), anodized aluminum, or silicon. The marker 25c includes a groove Pa1 formed on the part P by laser processing and an unevenness on the surface of the groove Pa1.

When the part P is aluminum, stainless steel (SUS), anodized aluminum, or silicon, the marker 25c is engraved on the part P by irradiating the part P with a laser to finely scrape the surface thereof and create an unevenness on the surface of the formed groove Pa1. Since the size of the unevenness on the surface of the groove Pa1 is smaller than that of the unevenness created when the part P is quartz or ceramic, diffused reflection of light occurs, and the portion of the groove Pa1 looks white due to the diffused reflection of light.

As a result, when the light output from the reader hits the marker 25c, the reader reads a contrast of light by the amount of light reflected due to the unevenness of the groove Pa1 formed on the surface of the part. P. In addition, the contrast between the white color of the portion the groove Pa1 due to diffused reflection of light and the color of the other portions is read. The reader acquires the two-dimensional code information according to the read contrast of the light and/or the read contrast of color. Thus, information on the part P such as the part number, serial number, and date of manufacture of the part P included in the two-dimensional code information may be acquired.

Portion (d) of FIG. 2 illustrates a state of a part of the region Pa of the marker 25c engraved on the part P when the part P is aluminum or stainless steel. The marker 25c includes the color of the oxide film formed on the part P by laser processing and the color of the part P before discoloration.

When the part P is aluminum or stainless steel, and when the laser is irradiated to the part P, the part P is defocused to transfer heat to the extent that the part P does not melt. Thus, an oxide film Pa3 is formed on the surface of the part P by applying heat without scraping the part P, and the oxide film Pa3 looks black. Thus, a contrast occurs between the black color of the region Pa on which the oxide film Pa3 is formed and the color of aluminum or stainless steel in the other regions.

As a result, when the light output from the reader hits the marker 25c, the reader reads the contrast between the black color of the region Pa on which the oxide film Pa3 is formed and the color of the other portion. The reader then reads the two-dimensional code information according to the read contrast of color. Thus, information on the part P such as the part number, serial number, and date of manufacture of the part P included in the two-dimensional code information may be acquired.

However, when the part P illustrated in portion (d) of FIG. 2 is aluminum or stainless steel, the engraved portion including the region Pa may swell due to thermal expansion in order to transfer heat to the metal to develop color. In this case, the two-dimensional code information may be transferred to the swollen convex portion. In that case, it is possible to engrave the code. only in the white portion in the region Pa without forming the black portion in the region Pa.

In the case of any of the materials illustrated in FIG. 2, the part P is directly processed and the marker 25c is engraved on the part P. Thus, it is possible to prevent the marker 25c from adversely affecting the process such as etching. Further, in the case of a part P that is worn out by plasma such as the edge ring 25, by forming the groove Pa1 having a certain depth in the part P, even when the marker 25c is exposed to plasma, the marker 25c that is resistant to wear may be processed into the part P. Further, when the part P is easily worn out, it, is preferable that the marker 25c is formed at a position on the side surface or other surface of the part P that is not easily exposed to plasma and at a position where the reader may read the marker 25c.

In addition, in the above description, the marker 25c is engraved on the surface of the part P. However, the present disclosure is not limited thereto, and the marker 25c may form, for example, a groove (hollow space) inside the part P. When the marker 25c is formed inside the part P, the marker 25c is recognized by the color contrast due to the hollow space inside the part P. However, when the part P is transparent, the part P is also recognizable by the contrast of light.

As described above, the two-dimensional code information that may be read by the reader is embedded in the marker 25c engraved on the part P according to the embodiment. Further, the marker 25c has a function of correcting errors in the two-dimensional code information. The size and amount of information of the two-dimensional code information are determined by the cell size (size per dot), the number of cells (the number of dots constituting the two-dimensional code), and the error correction level (data restoration force).

For example, as the cell size becomes larger, the size per dot becomes larger, and thus, the information may be easily read. Further, as the number of cells becomes larger, the number of dots constituting the code becomes larger, and thus, the amount of information becomes larger. Further, as the error correction level becomes higher, the code size becomes larger, and thus, the amount of information becomes smaller.

However, as the error correction level becomes higher, the data restoration power becomes higher. Therefore, even when a portion of the marker 25c is damaged or soiled due to wear of the part P, information on the part P included in the two-dimensional code information may be acquired by error correction. From the above, the marker 25c is configured so that error correction of the two-dimensional code information is possible.

When the part P for the substrate processing apparatus is processed and the marker 25c is directly engraved on the part P by the above engraving method, the marker 25c is configured as a portion of the part P. As a result, even when the part P for the substrate processing apparatus is worn out, the marker 25c does not adversely affect the process.

Further, the marker 25c is configured so that the two-dimensional code information may be read by the groove formed in the part P by lowering and/or two or more types of colors. As a result, the information on the part P included in the two-dimensional code information may be acquired by reading the marker 25c with a reader. Further, since the marker 25c has a function of correcting the error of the two-dimensional code information, even when a portion of the marker 25c is scraped due to wear of the part P, the two-dimensional code information may be restored by using the error correction function.

When the marker 25c of the two-dimensional code according to the embodiment is engraved, the required engraving range may be reduced to about 1/13 as compared with the case where the serial number of the part is directly engraved on the part. This makes it easier to process the marker 25c at a position where the part P is not exposed to plasma. Further, since the two-dimensional code information embedded in the marker 25c may be acquired using the reader, it is not possible to visually acquire the information on the part P without using the reader. Thus, the information on the part P may be protected. Further, by acquiring and recording the two-dimensional code information embedded in the marker 25c using the reader, it is possible to contribute to shortening the recording work time and reducing recording errors.

[Substrate Processing System and Substrate Processing Apparatus]

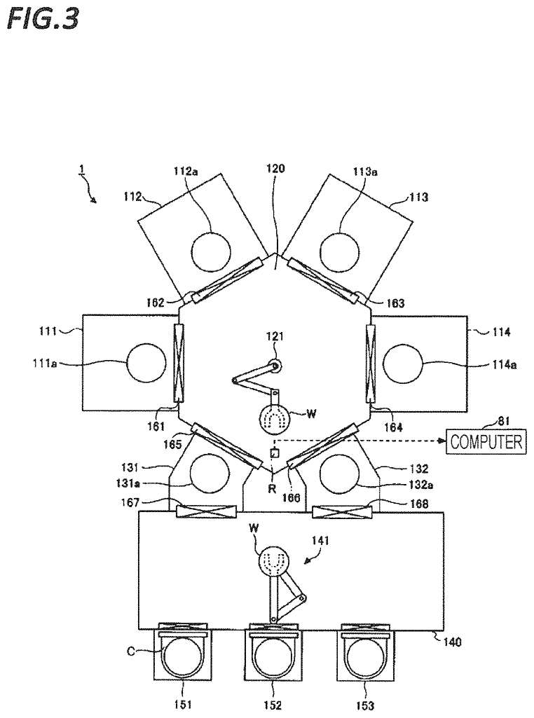

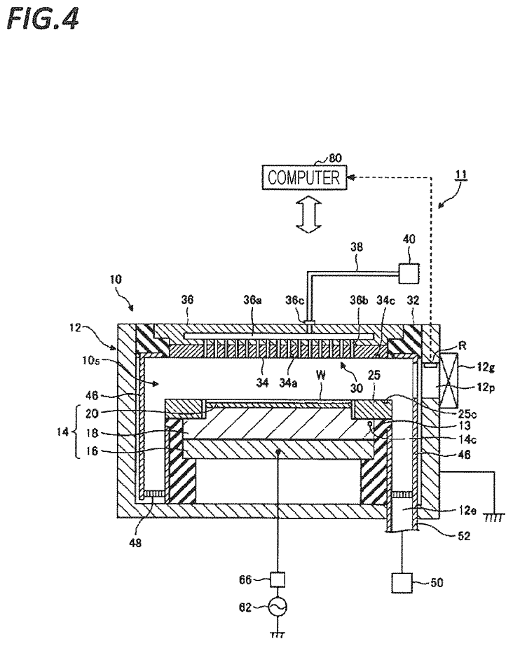

With reference to FIG. 3, descriptions will be made on a substrate processing system including a substrate processing apparatus on which the part engraved with the marker described above is placed, and a transfer chamber for transferring the substrate to the substrate processing apparatus. Further, the substrate processing apparatus will be described with reference to FIG. 4. FIG. 3 is a view illustrating the substrate processing system 1 according to the embodiment. FIG .4 is a schematic cross-sectional view illustrating the substrate processing apparatus 11 according to the embodiment. Although FIGS. 3 and 4 illustrate an embodiment in which a reader is mounted, it is also possible to use a portable type reader without mounting a reader on the substrate processing system and the substrate processing apparatus.

The substrate processing system 1 includes processing chambers 111 to 114, a vacuum transfer chamber 120, load lock chambers 131 and 132, an air transfer chamber 140, load ports 151 to 153, gate valves 161 to 168, and a computer 81. The vacuum transfer chamber 120 and the air transfer chamber 140 are examples of a transfer chamber. The processing chambers 111 to 114 are examples of a processing chamber of the substrate processing apparatus.

The processing chambers 111 to 114 include stages 111a to 114a on which the wafer W is placed, and are connected to the vacuum transfer chamber 120 via the gate valves 161 to 164. The inside of the processing chambers 111 to 114 is depressurized to a predetermined vacuum atmosphere, and the wafer W is subjected to a desired processing inside the processing chambers 111 to 114.

The inside of the vacuum transfer chamber 120 is depressurized to a predetermined vacuum atmosphere. The vacuum transfer chamber 120 is provided with a transfer mechanism 121, and the transfer mechanism 121 transfers the wafer W between the processing chambers 111 to 114 and the load lock chambers 131 and 132.

The load lock chambers 131 to 132 include stages 131a to 132a on which the wafer W is placed, and are connected to the vacuum transfer chamber 120 via gate valves 165 and 166 and are connected to the air transfer chamber 140 via gate valves 167 and 168. The load lock chambers 131 and 132 have a function of switching between an air atmosphere and a vacuum atmosphere,

The atmosphere inside the air transfer chamber 140 is an air atmosphere, and a transfer mechanism 141 is provided therein. The transfer mechanism 141 transfers the wafer W between the load lock chambers 131 and 132 and the carriers C of the load ports 151 to153.

The computer 81 controls the entire substrate processing system 1. For example, the computer 81 performs the operation of the processing chambers 111 to 114, the operation of the transfer mechanisms 121 and 141, the opening and closing of the gate valves 161 to 168, and the switching of the vacuum atmosphere or the air atmosphere in the load lock chambers 131 and 132. The computer 81 is an example of a controller that controls the entire substrate processing system 1.

In FIG. 3, the reader R is arranged in the vacuum transfer chamber 120, but the present disclosure is not limited thereto. The substrate W may be arranged at any position of the transfer path through which the substrate W is transferred to the processing chambers 111 to 114 of the substrate processing apparatus via the vacuum transfer chamber 120 and the air transfer chamber 140. For example, the reader R may be arranged in the processing chambers 111 to 114, the load lock chambers 131 and 132, the air transfer chamber 140, the load ports 151 to 153, and the gate valves 161 to 168. Further, the reader R is not limited to one, and a plurality of readers R may be arranged. As described above, it is also possible to use a portable type reader without mounting a reader on the substrate processing system and the substrate processing apparatus.

The reader R reads the two-dimensional code information from the markers engraved on the part P arranged in the processing chambers 111 to 114, the transferred part P, or the part P arranged in other chambers. The reader R transmits the read two-dimensional code information to the computer 81. The computer 81 acquires the part number, serial number, and date of manufacture of the part P from the received two-dimensional code information.

For example, when the marker 25c is engraved on the edge ring 25, the edge ring 25 is transferred through the path for transferring the substrate W. In this case, the marker 2.5c may be read by the reader R when the edge ring 25 is transferred, and the two-dimensional code information may be acquired. As a result, it is possible to facilitate the part management of the edge ring 25 to be replaced. Further, by reading the marker 25c with the reader R, it is possible to accurately manage whether the part arranged in the substrate processing apparatus is the product of the company or a product of the other company.

[Substrate Processing Apparatus]

Next, descriptions will be made on a configuration of the substrate processing apparatus 11 with reference to FIG. 4. The substrate processing apparatus 11 includes a chamber 10 having an internal space 10s, whereby, for example, the processing chambers 111 to 114 illustrated in FIG. 3 are formed. The chamber 10 includes a chamber body 12 having a substantially cylindrical shape. A passage 12p is formed in the side wall of the chamber body 12. A substrate W passes through the passage 12p when being transferred between the internal space 10s and the outside of the chamber 10. The passage 12p is configured to be opened and closed by a gate valve 12g. The gate valve 12g is provided along the side wall of the chamber body 12. The passage 12p is a passage through which the substrate W and the edge ring 25 are transferred, and the reader R is arranged therein. The reader R may be arranged on the gate valve 12g.

A support portion 13 is provided on the bottom of the chamber body 12. The support portion 13 has a substantially cylindrical shape and is formed of an insulating material. The edge ring 25 (also called a focus ring) and a mounting table 14 surrounding the periphery of the substrate are provided on the support portion 13. The edge ring 25 has a substantially cylindrical shape and may be formed of silicon. A marker 25c is engraved on the upper surface of the edge ring 25. However, the position of the marker 25c is not limited to the upper surface of the edge ring 25 as long as the marker 25c is readable by the reader R or another reader outside the substrate processing apparatus 11, and may be the side surface or the back surface of the edge ring 25 or may be formed inside the edge ring 25.

The substrate processing apparatus 11 includes a mounting table 14 in the internal space 10s. The mounting table 14 supports the substrate W. The mounting table 14 includes an electrostatic chuck 20, a lower electrode 18, and an electrode plate 16. The electrode plate 16 and the lower electrode 18 are formed of a conductive material such as, for example, aluminum and have a substantially disk shape.

The electrostatic chuck 20 is provided on the lower electrode 18. The electrodes of the electrostatic chuck 20 are connected to a DC power supply. When a voltage from a DC power supply is applied to the electrodes, the substrate W is held by the electrostatic chuck 20 by electrostatic attraction. The electrostatic chuck 20 supports the substrate W and the edge ring 25. A marker 14c is engraved on the side surface of the mounting table 14. However, the position of the marker 14c is not limited to the side surface of the edge ring 14 as long as the marker 14c is readable by the reader R or another reader outside the substrate processing apparatus 11, and may be the upper surface of the edge ring 14 or may be formed inside the mounting table 14.

An upper electrode 30 is provided above the mounting table 14. The upper electrode 30 is supported on the upper portion of the chamber body 12 via an insulating member 32. The upper electrode 30 may include a top plate 34 and a support body 36. The top plate 34 may be formed of a low-resistance conductor or semiconductor that generates little Joule heat. A plurality of gas ejection holes 34a is formed in the top plate 34. The plurality of gas ejection holes 34a penetrate the top plate 34 in the plate thickness direction.

A marker 34c is engraved on the lower surface of the top plate 34. However, the position of the marker 34c is not limited to the lower surface of the top plate 34 as long as the marker 14c is readable by the reader R or another reader outside the substrate processing apparatus 11, and may be the side surface of the top plate 34 or may be formed inside the top plate 34. Hereinafter, the reader R or another reader outside the substrate processing device 11 is also referred to as a “reader R.”

The support body 36 detachably supports the top plate 34. The support body 36 is formed of a conductive material such as aluminum. A gas diffusion chamber 36a is provided inside the support body 36. A plurality of gas holes 34a is formed in the support body 36. The plurality of gas holes 36b extend downward from the gas diffusion chamber 36a. The plurality of gas holes 36b communicate with the plurality of gas ejection holes 34a, respectively. A gas inlet 36c is formed in the support body 36. The gas inlet 36c is connected to the gas diffusion chamber 36a. A gas supply pipe 38 is connected to the gas inlet 36c, and a gas source 40 is connected to the gas supply pipe 38. The gas from the gas source 40 passes through the gas supply pipe 38, passes through the plurality of gas holes 36b from the gas inlet 36c through the gas diffusion chamber 36a, and is introduced from the gas ejection hole 34a.

In the substrate processing apparatus 11, a shield 46 is detachably provided along the inner wall surface of the chamber body 12. The shield 46 is also provided on the outer periphery of the support portion 13. The shield 46 prevents the etching by-product from adhering to the chamber body 12.

A baffle plate 48 is provided between the support portion 13 and the side wall of the chamber body 12. The baffle plate 48 is constituted by forming a film having corrosion resistance on the surface of a member formed of, for example, aluminum. A plurality of through holes is formed in the baffle plate 48. An exhaust port 12e is provided below the baffle plate 48 and at the bottom of the chamber body 12. The exhaust port 12e is connected to an exhaust device 50 via an exhaust pipe 52.

The substrate processing apparatus 11 includes a radio-frequency power supply 62 for applying a power of radio-frequency RF. The radio-frequency power supply 62 is connected to the electrode plate 16 via a matching device 66 and is configured to generate a power of radio-frequency RF in order to generate plasma from the gas in the chamber 10. The frequency of the radio-frequency RF is, for example, in the range of 27 MHz to 100 MHz.

The substrate processing apparatus 11 may further include a computer 80. The computer 80 is an example of a controller that controls each unit of the substrate processing apparatus 11. The computer 80 executes a control program and controls each unit of the substrate processing apparatus 11 according to the recipe data, so that various processes are executed in the substrate processing apparatus 11.

In the substrate processing apparatus 11 having such a configuration, the top plate 34 on which the marker is engraved, the edge ring 25, and the mounting table 14 are mentioned as examples of the part for the substrate processing apparatus 11, but the present disclosure is not limited thereto. For example, other examples of the part for the substrate processing apparatus 11 include a baffle plate 48 and a shield 46, and a marker may be engraved on these members.

[Part Management System]

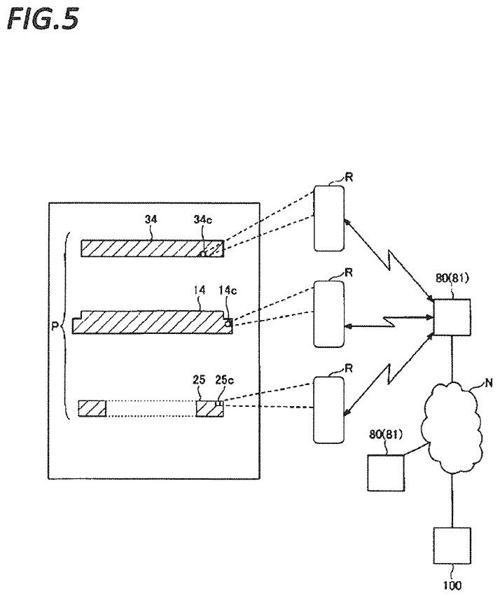

Next, with reference to FIG. 5, descriptions will be made on an example of a part management system to which the computer 80 that controls the substrate processing apparatus 11 and the computer 81 that controls the substrate processing system 1 are connected. FIG. 5 is a view illustrating an example of the part management system according to the embodiment.

A part P arranged in the substrate processing apparatus 11 and a part P arranged in the substrate processing system 1 are engraved with markers (34c, 14c, and 25c). The reader R reads the two-dimensional code information of the markers engraved on the part P and transmits such information to the computer 80 that controls the substrate processing apparatus 11 or the computer 81 that controls the substrate processing system 1.

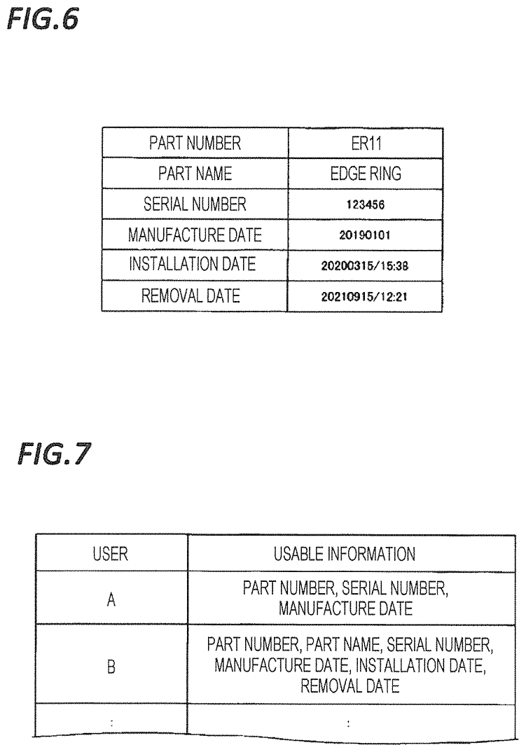

The computer 80 and the computer 81 record information on the part P included in the two-dimensional codeformation on the recording medium. FIG. 6 is a view illustrating an example of information on the part included in the two-dimensional code information according to the embodiment.

The computer 80 and the computer 81 record, for example, the part number “ER11,” the part name “edge ring,” the serial number “123456,” and the date of manufacture “20109010” as information on the part P on the recording medium. Further, the installation date and time “201015/15:38” and the removal date and time “20210915/12:21” are recorded on the recording medium. In particular, the part number, serial number, and date of manufacture are always embedded in the marker. As a result, the computer 80 and the computer 81 may identify the part P by acquiring the part number, the serial number, and the date of manufacture.

The computer 80 and the computer 81 are connected to a host computer 100 via a network N. The number of computers 80 and 81 is not limited to two, and may be any number. The host computer 100 may be a computer on the cloud.

The computer 80 and the computer 81 may transmit information on the part P to the host computer 100. The host computer 100 may store information on the part P received from the computer 80 and the computer 81 in a recording medium and use the information for part management as history information.

The timing of collecting information on the part P will be described. A part supplier or a manufacturer of a substrate processing apparatus directly engraves a two-dimensional code marker containing information such as a serial number on a part P shipped to a customer. Then, in order to know which part P has been shipped, the two-dimensional code information embedded in the marker engraved with the reader R is read before customer shipment, and the read information on the part P is recorded on a recording medium such as the host computer 100. When manufacturing the substrate processing apparatus 11, information on the part P such as a serial number is recorded so that it may be known which part P is incorporated and into which substrate processing apparatus 11 the part P is incorporated when incorporating a new part P into the substrate processing apparatus 11 or removing a worn part P. the reader R reads the two-dimensional code information embedded in the marker., and records the read information on a recording medium such as the host computer 100. Thus, based on the recorded information on the part P, it is possible to manage which part is attached to/detached from, to/from which apparatus the part is attached/detached, and when the part is attached to/detached from.

For example, the presence or absence of the part manufactured by a third party may be confirmed by comparing the two-dimensional code information read at the time of shipment with the two-dimensional code information read at the time of attachment/detachment of the part P. Further, by recording the operation information of the substrate processing apparatus 11 on a recording medium such as the host computer 100, the operation time of each part P may be calculated, and the correlation with the process characteristics may be easily confirmed.

Next, an example of using information on the part P will be described. When a trouble occurs in each of the substrate processing apparatuses 11, the host computer 100 and the computers 80 and 81 may extract the accumulated information on the part P and use such information for investigating the trouble. Further, based on the accumulated information on the part P, the correlation with the process result such as etching may be confirmed, which may be used when performing a finer and more complicated process.

For example, when the substrate processing apparatus 11 is installed, by reading the marker engraved on the part P with the reader R, it is possible to quickly grasp which part P is used in the installed substrate processing apparatus 11, and to efficiently manage and analyze the part.

In addition, when the part P is removed from the substrate processing apparatus 11, by reading the marker formed on the part P to be removed, it is possible to quickly grasp when and where the manufactured part P is removed from the substrate processing apparatus 11, and to efficiently perform a part management and analysis.

Further, for example, the cumulative time of use for each part P may be managed from the history information of the installation date and time of the substrate processing apparatus 11 and the history information of the date and time when the part is removed from the substrate processing apparatus 11. Also, when a trouble such as damage or failure occurs in the part P from the history information, it is possible to quickly investigate the part P in which the damage or failure has occurred.

The host computer 100 and the computers 80 and 81 may limit the information that is usable among the history information accumulated by the user. FIG. 7 is a view illustrating an example of usable information set for each user according to the embodiment.

In the example of FIG. 7, the user “A” may use the part number, serial number, and manufacturing date of the recorded history information. For example, when the host computer 100 or computers 80 and 81 display the history information on the part P on the display unit of the terminal device owned by the user “A,” information on the part number, serial number, and date of manufacture is displayed on the display unit, and other information is not displayed thereon.

Meanwhile, the user “B” may use the part number, the part name, the serial number, the date of manufacture, the date and time of installation, and the date and time of removal from the recorded history information. That is, the history information on the part P displayed on the terminal device owned by the user “A” and the history information on the part P displayed on the terminal device owned by the user “B” are different from each other. Thus, the disclosure range of the history information on the part P may be managed for each user.

As described above, in the part P for the substrate processing apparatus according to the embodiment, a marker whose serial number is encoded is directly formed on the part P by laser processing. The reader R acquires the two-dimensional code information embedded in the marker and records the information on a recording medium such as the host computer 100. This may contribute to shortening; the recording work time and reducing recording errors. Further, by recording the read two-dimensional code information on a recording medium such as the host computer 100, it is possible to accumulate history information of parts in one or more substrate processing apparatuses 11. As a result, it is possible to quickly manage, investigate, and analyze parts based on the accumulated history information of parts.

By putting the marker engraved on the part in a finder screen of the reader or camera, it is possible to implement an augmented reality (AR) function that superimposes and displays virtual contents corresponding to the marker on a display under a real environment. In this case, the content information associated with the marker is stored in advance in the host computer 100. Then, when the marker is read by the reader or camera, the content information associated with the marker is transmitted from the host computer 100 to the reader or camera, As a result, a desired content may be displayed on the display unit of the reader or camera.

The substrate processing apparatus of the present disclosure is applicable to any type of apparatuses among an atomic layer deposition (ALD) apparatus, capacitively coupled plasma (CCP), an inductively coupled plasma (ICP), a radial line slot antenna (RLSA), an electron cyclotron resonance plasma (ECR), and a helicon wave plasma (HMP).

According to an aspect of the present disclosure, it is possible to improve the part management for the substrate processing apparatus.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, the true scope and spirit being indicated by the following claims.

What is claimed is:

1. A part for substrate processing apparatus, comprising:
a marker with at least one of a surface and an inside of the part processed,
wherein the marker is configured such that two-dimensional code information is readable by at least one of a groove formed in the part by processing and two or more types of colors.

2. The part for substrate processing apparatus according o claim 1, wherein the marker is configured such that the two-dimensional code information is readable by a contrast of light incident on the groove formed on at least one of a surface and an inside of the part.

3. The part for substrate processing apparatus according to claim 2, wherein the marker is configured such that the two-dimensional code information is readable by a contrast of the two or more types of colors formed on at least one of the surface and the inside of the part.

4. The part for substrate processing apparatus according to claim 3, wherein the part is quartz, and
the marker is configured with the groove formed in the part by laser processing.

5. The part for substrate processing apparatus according to claim 3, wherein the part is ceramic, and
the marker is configured with the groove formed in the part by laser processing,
a color discolored by laser processing, and a color of the part before discoloration.

6. The part for substrate processing apparatus according to claim 3, wherein the part is aluminum, stainless steel, anodized aluminum, or silicon, and
the marker is configured with the groove formed in the part by laser processing and an unevenness on a surface of the groove.

7. The part for substrate processing apparatus according to claim 3, wherein the part is aluminum or stainless steel, and
the marker is configured with a color of an oxide film formed in the part by laser processing and a color of the part before discoloration.

8. The part for substrate processing apparatus according to claim 7, wherein the marker is configured such that the two-dimensional code information is readable by a reader.

9. The part for substrate processing apparatus actor claim 8, wherein the marker is configured such that an error correction of the two-dimensional code information is possible.

10. The part for substrate processing apparatus according to claim 1, wherein the marker is configured such that the two-dimensional code information is readable by a contrast of the two or more types of colors formed on at least one of a surface and an inside of the part.

11. The part for substrate processing apparatus according to claim 1, wherein the part is quartz, and
the marker is configured with the groove formed in the part by laser processing.

12. The part for substrate processing apparatus according to claim 1, wherein the part is ceramic, and
the marker is configured with the groove formed in the part by laser processing, a color discolored by laser processing, and a color of the part before discoloration.

13. The part for substrate processing apparatus according to claim 1, wherein the part is aluminum, stainless steel, anodized aluminum, or silicon, and
the marker is configured with the groove formed in the part by laser processing and an unevenness on a surface of the groove.

14. The part for substrate processing apparatus according to claim 1, wherein the part is aluminum or stainless steel, and
the marker is configured with a color of an oxide film formed in the part by laser processing and a color of the part before discoloration.

15. The part for substrate processing apparatus according to claim 1, wherein the marker is configured such that the two-dimensional code information is readable by a reader.

16. The part for substrate processing apparatus according to claim 1, wherein the marker is configured such that an error correction of the two-dimensional code information is possible.

17. A substrate processing system comprising: a substrate processing apparatus in which the part according to claim 1 is disposed;
a transfer chamber configured to transfer a substrate to the substrate processing apparatus;
a reader that is disposed in one of paths through which the substrate is transferred to the substrate processing apparatus via the transfer chamber; and
a controller configured to control an overall operation of the substrate processing system,
wherein the reader reads the two-dimensional code information from the marker formed in at least one of the part provided in the substrate processing apparatus and the part transferred through e path, and
the controller acquires information on the part included in the two-dimensional code information read by the reader and records the information on the part on a recording medium.
